(19) United States
(12) Patent Application Publication
(10) Pub. No.: US 2009/0321778 A1
(43) Pub. Date: Dec. 31, 2009

(54) FLIP-CHIP LIGHT EMITTING DIODE AND METHOD FOR FABRICATING THE SAME

(75) Inventors: TUNG-AN CHEN, HuKou (TW); CHIH-PENG HSU, HsinChu (TW); CHUNG-MIN CHANG, HuKou (TW); TSE-AN LEE, HuKou (TW)

Correspondence Address: PCE INDUSTRY, INC.;ATT. Steven Reiss, 288 SOUTH MAYO AVENUE, CITY OF INDUSTRY, CA, 91789, US

(73) Assignee: ADVANCED OPTOELECTRONIC TECHNOLOGY, INC., Hsinchu Hsien (TW)

(21) Appl. No.: 12/487,821

(22) Filed: Jun. 19, 2009

(30) Foreign Application Priority Data
Jun. 30, 2008 (CN) 200810302460.4

(51) Int. Cl. H01L 33/00; H01L 21/768

(52) U.S. Cl. 257/99; 438/26; 257/E33.056; 257/E33.066; 257/E21.575

(57) ABSTRACT

A flip-chip light emitting diode includes a substrate, an LED chip and a plurality of conductive bumps. The substrate has at least one recess defined in the surface of the substrate, and at least a part of the conductive bumps is embedded the at least one recess. The LED chip is mounted on a surface of the substrate by a flip-chip mounting process. The conductive bumps are sandwiched between the substrate and the LED chip to bond and electrically connect the LED chip to the substrate.

### BACKGROUND

1. Technical Field

The disclosure relates to flip-chip light emitting diodes (LEDs) and fabrication methods thereof, and more particularly, to a flip-chip LED with a stable and secure connection between a chip and a submount, and a method for fabricating the flip-chip LED.

2. Description of Related Art

A flip-chip semiconductor package refers to a package structure using a flip-chip technique to electrically connect an active surface of a chip to a surface of a structure via a plurality of conductive bumps. A plurality of solder balls are implanted on another surface of the substrate and serves as input/output (I/O) connections to allow the chip to be electrically connected to an external device. In the above arrangement, the size of the semiconductor package can be significantly reduced such that the chip may be made dimensionally closer to that of the substrate, and the semiconductor package does not require bonding wires, thereby reducing impedance and improving the electrical performance of the semiconductor package. These advantages make the flip-chip packaging technology become the mainstream packaging technology.

Referring to FIG. 12, a typical flip-chip light emitting diode 60 includes a 61, two submounts 62, and a chip 63. The housing 61 has a cavity 610, and the two submounts 62 are positioned on a bottom of the cavity 610. An active surface of the chip 63 is electrically connected to the submounts 62 by a plurality of conductive bumps 64. The conductive bumps 64 may be metal bumps or solder bumps. Light is emitted upwards from the side of the chip 63, and the electrodes (not shown) of the chip 63 are located at the active surface of the chip 63 to contact the submounts 62, so it does not have the problem of absorbing or covering light. However, the chip 63 tends to translocate with respect to the submounts 62 due to the bonding strength of the conductive bumps 64 and the submounts 62, resulting in a poor electrical connection between the chip 63 and the submounts 62. In addition, the conductive bumps 64 may translocate to an undesirable location during the process of joining the chip 63 to the submounts 62.

Therefore, what is needed is to provide a flip-chip LED with a stable and secure connection between the chip and the submount, and a method for fabricating the flip-chip LED.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic cross-section of a first embodiment of a flip-chip light emitting diode (LED).

FIG. 2 is a schematic cross-section of a second embodiment of a flip-chip LED.

FIG. 3 is a schematic cross-section of a third embodiment of a flip-chip LED.

FIG. 4 is a schematic cross-section of a fourth embodiment of a flip-chip LED.

FIGS. 5-11 are schematic flowcharts of an embodiment of a method of fabricating a flip-chip LED.

FIG. 12 is a schematic cross-section of a typical flip-chip LED.

### DETAILED DESCRIPTION

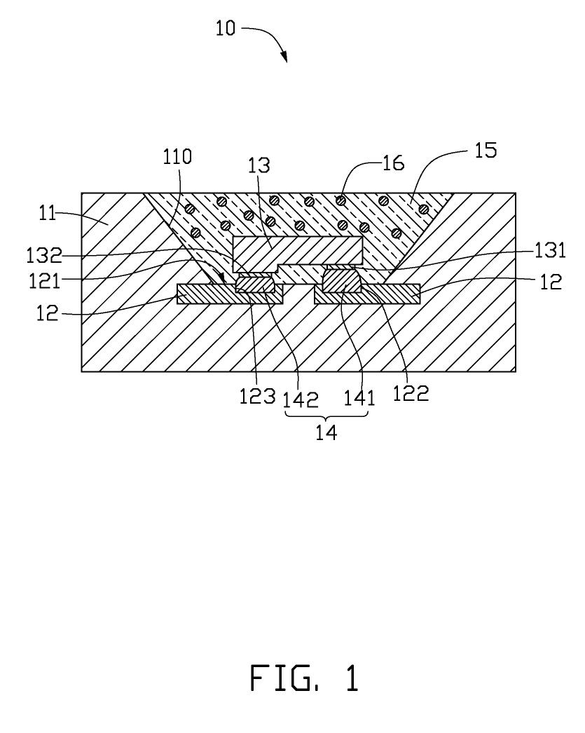

Referring to FIG. 1, a first embodiment of a flip-chip light emitting diode (LED) 10 is provided. The flip-chip LED 10 includes a housing 11, a substrate 12, and an LED chip 13, a plurality of conductive bumps 14, and an encapsulant 15.

The housing 11 has a cavity 110. The material of the housing may be a liquid crystal polymer or plastics.

The substrate 12 is positioned on a bottom of the cavity 110 for accommodating the LED chip 13. The substrate 12 holds the LED chip 13 and may be electrically connected with a power supply (not shown) to supply electrical power to the LED chip 13. In the illustrated embodiment, the substrate 12 may be a lead frame, which is made of high conductivity metal, such as gold (Au), silver (Ag), copper (Cu), or any other metal. The substrate 12 has an interface surface 121 exposed on the bottom of the cavity 110, and a first recess 122 and a substantially symmetrical juxtaposed second recess 123 defined in the interface surface 121 of the substrate 12. The first recess 122 and the second recess 123 may be square grooves, hemispherical grooves, or other grooves.

The LED chip 13 may be a gallium nitride (GaN) based LED chip, AlInGaN based LED chip, gallium arsenide (GaAs) based LED chip, gallium phosphide (GaP) based LED chip, or AlInGaP based LED chip. Light with a desired wavelength can be emitted from the LED chip 13 when the driving current passing through the LED chip 13. For example, the LED chip 13 is a GaN LED chip, which includes a sapphire substrate, a buffer layer, an n-type GaN layer, active layer with multiple quantum well (MQW) therein, p-type GaN layer, a first electrode, and a second electrode. The present embodiment utilizes a GaN based LED chip, for example. The LED chip 13 is positioned in the cavity 110 and mounted on the substrate 12 by a flip-chip mounting process. The LED chip 13 has a first electrode 131 and a second electrode 132, both located at one side of the LED chip 13 and electrically connected to the substrate 12 by the conductive bumps 14.

The conductive bumps 14 are sandwiched between the substrate 12 and the LED chip 13 in order to bond the LED chip 13 to the substrate 12 and establishing an electrical connection to each other. The conductive bumps 14 may be metal bumps (such as gold bumps), or solder bumps (such as block tin). The material of the conductive bumps 14 may vary depending on the material of the substrate 12 and process condition of making the LED. For example, the material of the conductive bumps 14 may have a high melting point such as Pb-95 wt % Sn-5 wt % alloy, or a low melting point such as In-51 wt % Bi-32.5 wt % Sn-16.5 wt % alloy, Pb-63 wt % Sn-37 wt % alloy and Pb-50 wt % In-50 wt % alloy. In the illustrated embodiment, each conductive bump 14 includes a first solder bump 141 and a second solder bump 142, both are In-51 wt % Bi-32.5 wt % Sn-16.5 wt % alloy. The first bump 141 is partly embedded in the first recess 122 of the substrate 12 and electrically connected to the first electrode 131 of the LED chip 13, and the second bump 142 is partly embedded in the second recess 123 of the substrate 12 and electrically connected to the second electrode 132 of the LED chip 13. Since the bumps 141, 142 are securely fixed in the first recess 122 and second recess 123, the bonding strength of the conductive bumps 14 and the substrate 12 is high and the electrical connection between the LED chip 13 and the substrate 12 is improved. In addition, sectional areas of the first bump 141 and the second bump 142 may be respectively less than sectional areas of the first and second recesses 122, 123.

The encapsulant 15 is positioned in the cavity 110, and encapsulates the LED chip 13 to protect the LED chip 13 from mechanical damage, moisture, and atmospheric exposure. The encapsulant 15 may be silicone resin, or other electrically insulating transparent materials. The encapsulant 15 may further include a plurality of phosphor particles 16 doped therein. The phosphor particles 16 are configured for converting light emitted from the LED chip 13 into a desired wavelength. For example, some phosphor materials are capable of absorbing light rays emitted from the LED chip 13 and emit red wavelength rays, green wavelength rays, yellow wavelength, or any other colors. It is understood that properly mixing these color wavelength rays can produce white light.

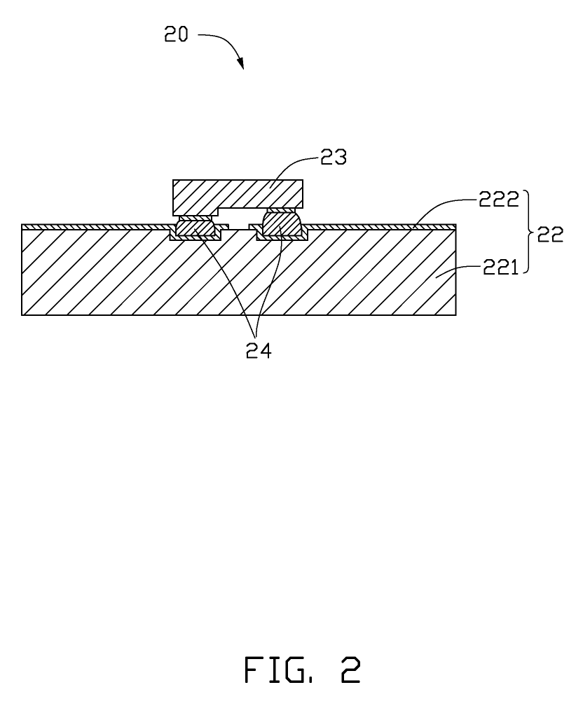

Referring to FIG. 2, a second embodiment of a flip-chip LED 20 is similar to the first embodiment of the flip-chip LED 10, except that a substrate 22 includes a dielectric layer 221 and a conductive layer 222 attached to the dielectric layer 221 and positioned at opposite sides of an LED chip 23. The LED chip 23 is electrically connected to the conductive layer 222 by the conductive bumps 24. A material of the dielectric layer 221 may include ceramic, silicon, aluminum nitride, boron nitride, silicon carbide, or any other dielectric material. The conductive layer 222 may be made of Au, Ag, Cu or any other conductive material. It may be appreciated that the substrate 22 may be a metal core PCB or an aluminum substrate.

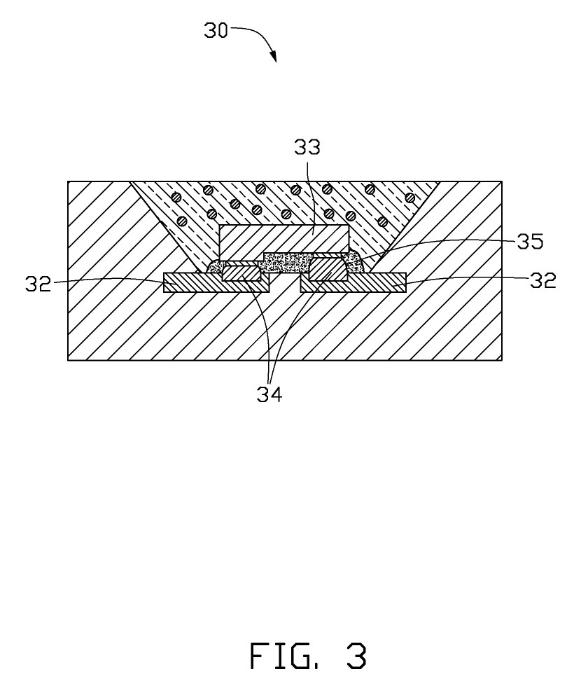

Referring to FIG. 3, a third embodiment of a flip-chip LED 30 is similar to the first embodiment of the flip-chip LED 10, except that the flip-chip LED 30 further includes an underfill material 35. The underfill material 35 is positioned in a gap between an LED chip 33 and a substrate 32 to insulate the LED chip 33 from the substrate 32, except for a connection between the LED chip 33 and the substrate 32 via the conductive bumps 34. The underfill material 35 also provides additional adhesion protection. Thus, short circuits and high electrical electrode breakdowns for the flip-chip LED 30 can be avoided, and improved stability of the connection between the LED chip 33 and the substrate 32. The underfill material 35 may include flexible colloidal insulating material, such as polymeric insulating gel or flux, so long as the hardness of the underfill material 35 is less than that of the conductive bumps 34.

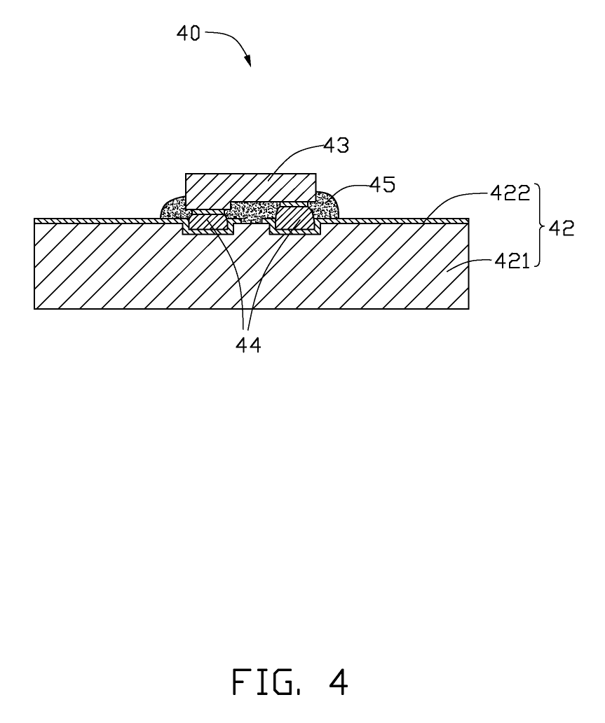

Referring to FIG. 4, a fourth embodiment of a flip-chip LED 40 is similar to the second embodiment of the flip-chip LED 20 except that the fourth embodiment of the flip-chip LED 40 further includes the underfill material 45. The underfill material 45 is positioned in a gap between an LED chip 43 and a substrate 42, except for a connection between the LED chip 43 and a conductive layer 422 of the substrate 42 located on a dielectric layer 421 of the substrate 42 via the conductive bumps 44. The underfill material 45 provides more adhesion protection at the LED chip 43. Thus, short circuits and high electrical electrode breakdowns for the flip-chip LED 40 can be avoided, and improved stability of the connection between the LED chip 43 and the substrate 42. The underfill material 45 may include flexible colloidal insulating material, such as polymeric insulating gel or flux, so long as the hardness of the underfill material 45 is less than that of the conductive bumps 44.

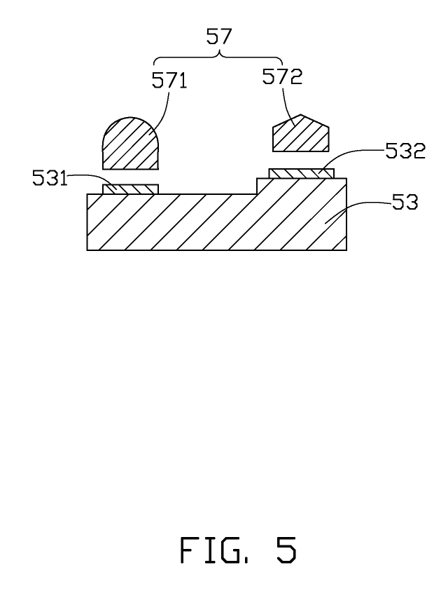

Referring to FIGS. 5-11, an embodiment of a method for fabricating the flip-chip LED 30 is provided. Depending on the embodiment, certain of the steps described below may be removed, others may be added, and the sequence of steps may be altered. It is also to be understood that the above description and the claims drawn to a method may include some indication in reference to certain steps. However, the indication used is only to be viewed for identification purposes and not as a suggestion as to an order for the steps. The method includes the following steps:

As shown in FIG. 5, an LED chip 53 and a plurality of conductive bumps 57 are provided. The LED chip 53 has a first electrode 531 and the second electrode 532. Each conductive bump 57 includes a first bump 571 and a second bump 572. The first bump 571 may have a hemispherical-shaped end, and the second bump 572 may have a conical-shaped end. The conductive bumps 57 may be formed by vapor plating, deposition, electroplating, or any other suitable method.

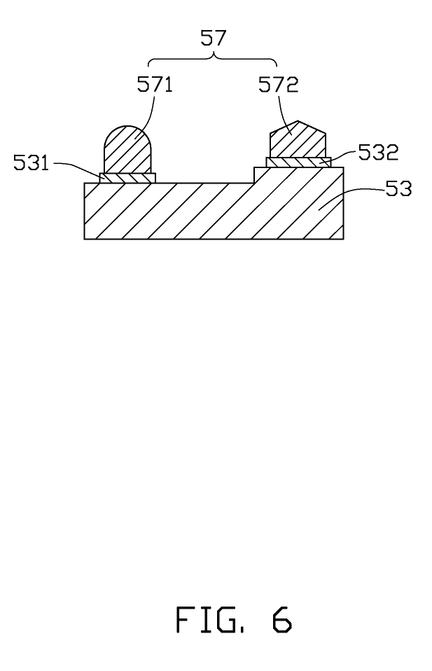

As shown in FIG. 6, the conductive bumps 57 are attached to the LED chip 53. Particularly, the opposite end of the hemispherical-shaped end of the first bump 571 contacts the first electrode 531 of the LED chip 53, and the opposite end of the conical-shaped end of the second bump 572 contacts the second electrode 532 of the LED chip 53.

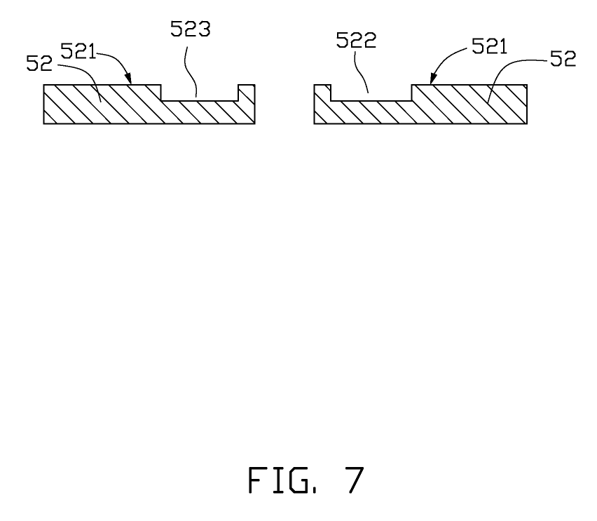

As shown in FIG. 7, a substrate 52 is provided, which has a first recess 522 and a second recess 523 defined in the substrate 52. The first recess 522 may be slightly larger than the first bump 571, and the second recess 523 may be slightly larger than the second bump 572.

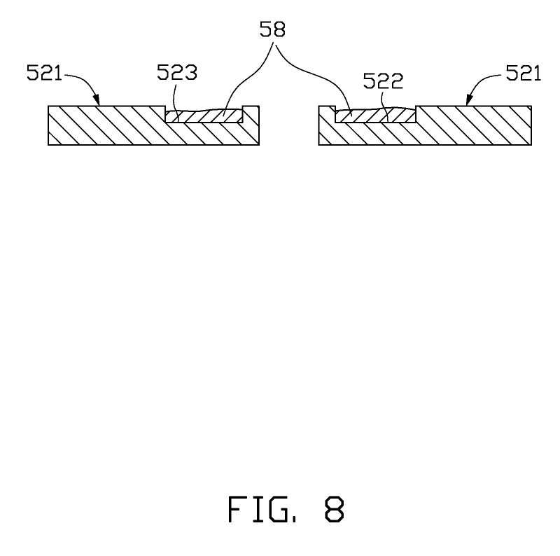

As shown in FIG. 8, a conductive material 58 is positioned in the first recess 522 and the second recess 523.

The material of the conductive material 58 may be the same as that of the conductive bumps 57. Since the first recess 522 and second recess 523 may be respectively larger than the first bump 571 and second bump 572, the first bump 571 and second bump 572 will be substantially connected with the conductive material 58.

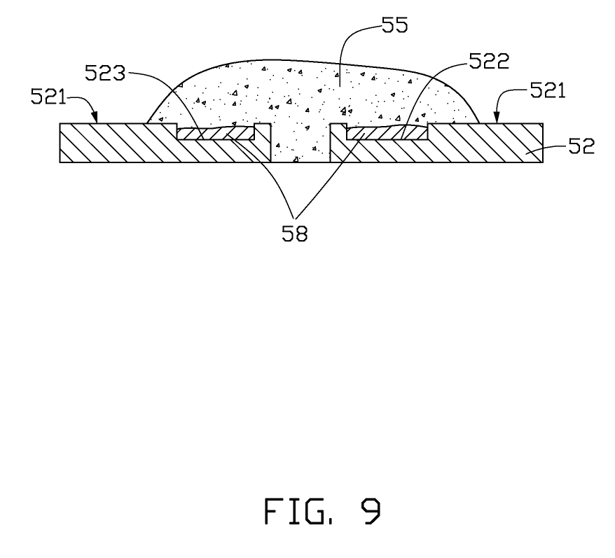

As shown in FIG. 9, an underfill material 55 is formed on the surface 521 of the substrate 52 to cover the first and second recesses 522, 523 and the conductive material 58. The underfill material 55 may be formed by printing, coating, dispensing, or any other suitable method.

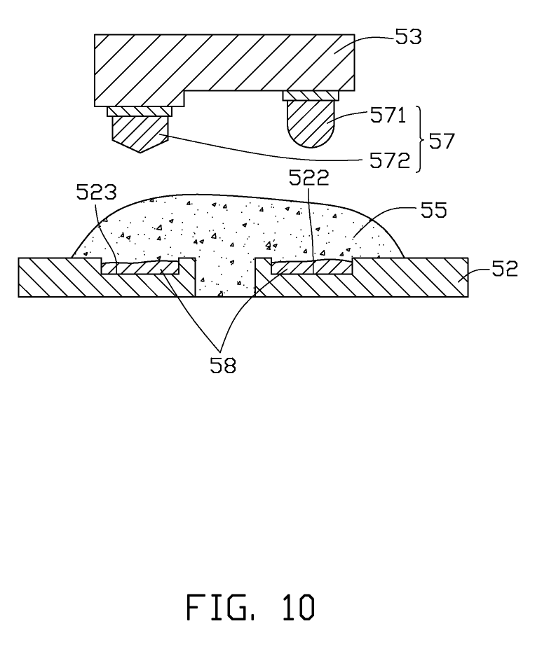

As shown in FIG. 10, the LED chip 53 and the conductive bumps 57 together are pressed against the conductive material 58 on the substrate 52. Particularly, the hemispherical-shaped end of the first bump 571 is pressed into the conductive material 58 located in the first recess 522, and the conical-shaped end of the second bump 572 is pressed into the conductive material 58 located in the second recess 523. Since the hardness of the conductive bumps 57 and the conductive material 58 are greater than that of the underfill material 55, the underfill material 55 will extrude out from the first and second recesses 522, 523 thereby covering a peripheral portion of the conductive bumps 57 during the pressing process, such that the first and second bumps 571, 572 will be directly connected to the conductive material 58. The hemispherical-shaped and conical-shaped ends aid in extruding the conductive material 58.

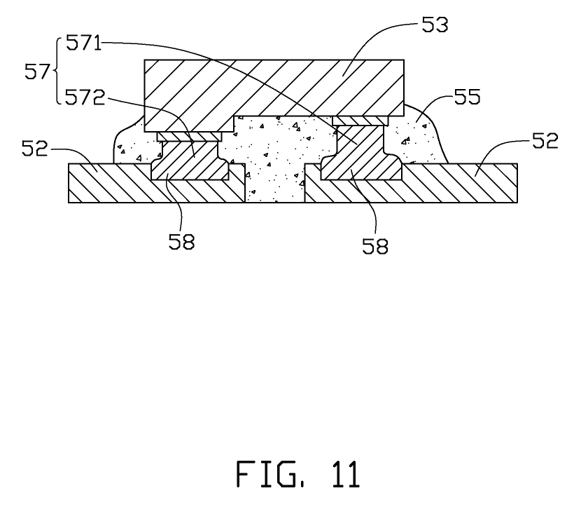

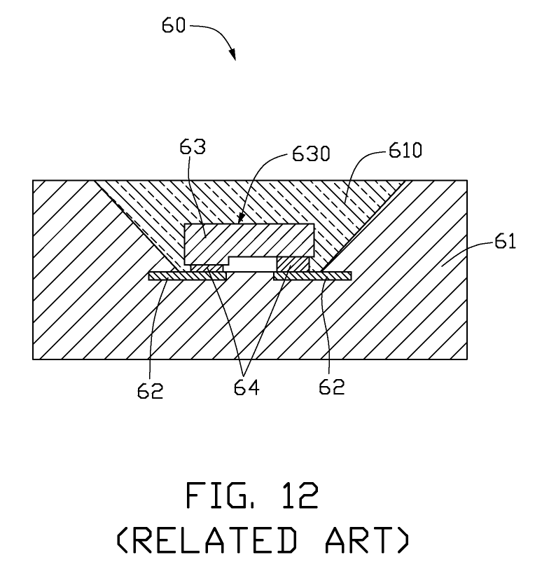

As shown in FIG. 11, the conductive bumps 57 and the conductive material 58 are melted to ensure the LED chip 53 is firmly connected to the substrate 52. Furthermore, the underfill material 55 fills a gap between the LED chip 53 and the substrate 52 except for the connection between the conductive bumps 57 and the conductive material 58, to further prevent translocation of the conductive bumps 57.

It is believed that the embodiments and their advantages will be understood from the foregoing description, and it will be apparent that various changes may be made thereto without departing from the spirit and scope of the embodiments or sacrificing all of its material advantages.

What is claimed is:

1. A flip-chip light emitting diode (LED), comprising:
a substrate;
an LED chip mounted on a surface of the substrate by a flip-chip mounting process;
a plurality of conductive bumps sandwiched between the substrate and the LED chip, to bond and electrically connect the LED chip to the substrate;
wherein the substrate has at least one recess defined in the surface of the substrate, and at least a part of the conductive bumps is embedded the at least one recess.

2. The flip-chip light emitting diode of claim 1, further comprising a housing having a cavity defined therein; the substrate is positioned on a bottom of the cavity.

3. The flip-chip light emitting diode of claim 2, further comprising an encapsulant positioned in the cavity encapsulating the LED chip.

4. The flip-chip light emitting diode of claim 1, wherein the substrate is selected from the group consisting of a lead frame, a metal core PCB, and an aluminum substrate.

5. The flip-chip light emitting diode of claim 1, wherein the substrate comprises a dielectric layer and a conductive layer attached to the dielectric layer; the LED chip is electrically connected to the conductive layer via the conductive bumps.

6. The flip-chip light emitting diode of claim 1, wherein each conductive bump comprises a first bump and a second bump; the at least one recess comprises a first recess and a second recess, both defined in the surface of the substrate; the first bump is embedded the first recess and the second bump is embedded the second recess.

7. The flip-chip light emitting diode of claim 1, wherein the at least one recess is larger than the conductive bumps.

8. The flip-chip light emitting diode of claim 1, further comprising an underfill material positioned in a gap between the LED chip and the substrate except at a connection of the LED chip and the substrate via the conductive bumps.

9. The flip-chip light emitting diode of claim 8, wherein the hardness of the underfill material is less than that of the conductive bumps.

10. The flip-chip light emitting diode of claim 1, wherein each conductive bump is selected from the group consisting of a metal bump and a solder bump.

11. The flip-chip light emitting diode of claim 1, wherein the material of the conductive bumps is selected from the group consisting of Pb-95 wt % Sn-5 wt % alloy, In-51 wt % Bi-32.5 wt % Sn-16.5 wt % alloy, Pb-63 wt % Sn-37 wt % alloy, and Pb-50 wt % In-50 wt % alloy.

12. A flip-chip light emitting diode (LED), comprising:
a substrate;
an LED chip mounted on a surface of the substrate by a flip-chip mounting process;
a plurality of conductive bumps sandwiched between the substrate and the LED chip, to bond and electrically connect the LED chip to the substrate, wherein one end of each conductive bump is inserted into the substrate, and the opposite end of each conductive bump is bonded to the LED chip; and
an underfill material positioned in a gap between the LED chip and the substrate except at a connection of the LED chip and the substrate via the conductive bumps.

13. The flip-chip light emitting diode of claim 12, wherein the hardness of the underfill material is less than that of the conductive bumps.

14. The flip-chip light emitting diode of claim 12, further comprising a housing having a cavity defined therein; the substrate is positioned on a bottom of the cavity.

15. The flip-chip light emitting diode of claim 14, further comprising an encapsulant positioned in the cavity encapsulating the LED chip.

16. The flip-chip light emitting diode of claim 12, wherein the substrate comprises a dielectric layer and a conductive layer attached to the dielectric layer; the LED chip is electrically connected to the conductive layer via the conductive bumps

17. The flip-chip light emitting diode of claim 12, wherein the substrate is selected from the group consisting of a lead frame, a metal core PCB, and an aluminum substrate.

18. A method for fabricating a flip-chip light emitting diode (LED), comprising:
providing an LED chip and a substrate, the substrate having at least one recess defined therein;
providing a plurality of conductive bumps and attaching the conductive bumps to the LED chip;
providing a conductive material and filling the at least of recess with the conductive material;
pressing the LED chip to the conductive material on the substrate to form a connection between the conductive bumps and the conductive material;
melting the conductive bumps and the conductive material to establish a firm connection between the conductive bumps and the conductive material.

19. The method of claim 18, wherein providing an underfill material on the substrate to cover the at least one recess and the conductive material before pressing the LED chip to the conductive material on the substrate.

20. The method of claim 18, wherein an end of each of the conductive bumps contacts the conductive material is hemispherical-shaped or conical-shaped.
